(19) United States
(12) Patent Application Publication
(10) Pub. No.: US 2025/0233566 A1
(43) Pub. Date: Jul. 17, 2025

(54) BIASING TECHNIQUES FOR LOW DISTORTION AMPLIFIERS

(71) Applicant: Analog Devices, Inc., Wilmington, MA (US)

(72) Inventor: Quan Wan, Belmont, MA (US)

(21) Appl. No.: 18/415,446

(22) Filed: Jan. 17, 2024

(51) Int. Cl. H03F 3/45

(52) U.S. Cl. CPC H03F 3/45475; H03F 2200/129

(57) ABSTRACT

Biasing techniques for reducing distortion in amplifiers are described. A regulation loop is used to keep the sum of collector currents of the input differential pair constant. The regulation loop includes an error correction amplifier that compares the sum of the input differential pair collector current with a reference current and adjusts a control voltage at a control terminal of a transistor to keep the current equal or proportional to the reference current.

### FIELD OF THE DISCLOSURE

This document pertains to electronic circuit design and, more specifically, to techniques for biasing amplifier circuits.

### BACKGROUND

Low-distortion amplifiers are important building blocks in many analog and mixed-signal systems. For example, they are widely used in the analog front-end of high-resolution ADCs and DACs. In these applications, the amplifier needs to faithfully preserve the signal's amplitude and phase information without introducing additional harmonics.

There are several nonidealities that can cause an amplifier to distort the signal, such as bias current modulation, nonlinearity in the transistors, noise, etc. Bias current modulation is one of the dominant distortion mechanisms in certain amplifier topologies. It arises because the bias current of the input differential pair can modulate with the input signal or other signals, leading to signal-dependent distortion.

To mitigate this issue, certain biasing techniques and compensation methods have been developed. These techniques generally aim to keep the bias current and/or operating points of the critical transistors constant over the signal swing. Some common approaches include using regulated cascode circuits, incorporating negative feedback, and adding correction circuits to cancel distortion-causing mechanisms.

By carefully analyzing the root causes of distortion and designing compensation methods, the total harmonic distortion (THD) performance of amplifiers may be improved dramatically. Low distortion amplifiers with THD in the −100 dB range or below have been demonstrated. These ultra-low distortion amplifiers enable high-performance data conversion and signal conditioning systems.

### SUMMARY OF THE DISCLOSURE

This disclosure is directed to biasing techniques for reducing distortion in amplifiers. The present inventor has recognized that a regulation loop may be used to keep the sum of collector currents of the input differential pair constant. The regulation loop includes an error correction amplifier that compares the sum of the input differential pair collector current with a reference current and adjusts a control voltage at a control terminal of a transistor to keep the current equal or proportional to the reference current.

In some aspects, this disclosure is directed to an amplifier circuit comprising: a differential pair of transistors configured and arranged to generate a summed current from individual ones of the differential pair of transistors; a transistor coupled with the differential pair of transistors; and an error correction amplifier coupled with a control terminal of the transistor and configured for: comparing a representation of the summed current to a representation of a reference current; and adjusting, based on the comparison, a voltage at the control terminal of the transistor.

In some aspects, this disclosure is directed to a method for biasing an amplifier circuit, the method comprising: coupling a transistor with a differential pair of transistors; generating a summed current from the differential pair of transistors; comparing, with an error correction amplifier coupled to a control terminal of the transistor, a representation of the summed current to a representation of a reference current; and adjusting, based on the comparison and with the error correction amplifier, a voltage at the control terminal of the transistor.

In some aspects, this disclosure is directed to an amplifier circuit comprising: a differential pair of transistors configured and arranged to generate a summed current from individual ones of the differential pair of transistors, the differential pair of transistors having a first control terminal to receive a first input signal and a second control terminal to receive a second input signal, wherein the differential pair of transistors is configured and arranged to generate a summed current; a transistor coupled with the differential pair of transistors, the transistor having a third control terminal; a first sense resistor coupled with the differential pair of transistors, wherein the first sense resistor is configured to generate a first voltage in response to the summed current from the differential pair of transistors; a reference current source coupled with the transistor and configured to generate a reference current; a second sense resistor coupled with the reference current source, wherein the second sense resistor is configured to generate a second voltage in response to the reference current; and an error correction amplifier having: a non-inverting input coupled with the first sense resistor and configured to receive the first voltage generated by the first sense resistor; and an inverting input coupled with the second sense resistor and configured to receive the second voltage generated by the second sense resistor.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a schematic diagram of an example of an operational amplifier circuit.

FIG. 2 is an example of an existing amplifier circuit.

FIG. 3 is a schematic diagram of an example of an amplifier circuit that can implement various techniques of this disclosure.

FIG. 4 is a schematic diagram of another example of an amplifier circuit that can implement various techniques of this disclosure.

FIG. 5 is a schematic diagram of another example of an amplifier circuit that can implement various techniques of this disclosure.

FIG. 6 illustrates an aspect of the subject matter in accordance with one embodiment.

FIG. 7 is a flow diagram of an example of a method for operating an amplifier circuit.

### DETAILED DESCRIPTION

The present inventor has recognized that amplifier distortion may occur when a bias current of an input differential pair modulates with an input signal. This modulation is caused by a finite output impedance of a bias current source and parasitic capacitances coupling signals into the bias node.

This disclosure is directed to biasing techniques for reducing distortion in amplifiers. The present inventor has recognized that a regulation loop may be used to keep the sum of collector currents of the input differential pair constant. The regulation loop includes an error correction amplifier that compares the sum of the input differential pair collector current with a reference current and adjusts a control voltage at a control terminal of a transistor to keep the current equal or proportional to the reference current.

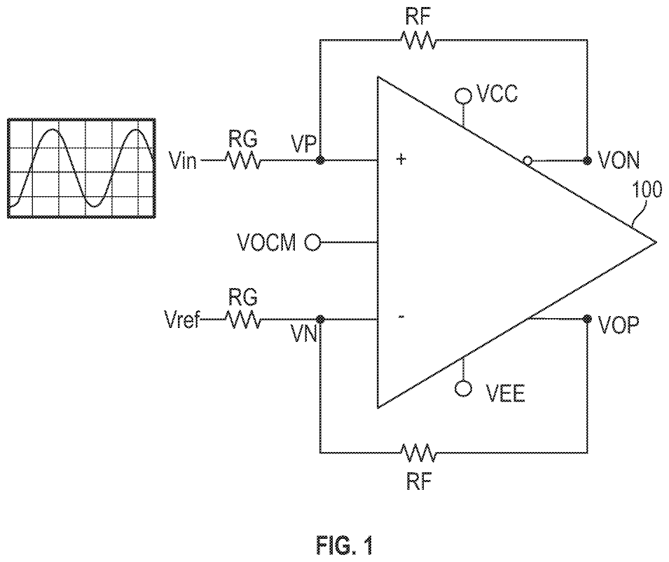

FIG. 1 is a schematic diagram of an example an operational amplifier circuit. The operational amplifier circuit 100 is configured for single-ended to differential conversion. In such a configuration, the reference voltage VREF is at a fixed DC voltage, and the input node is receiving a time-varying input signal VIN. Therefore, both the VP and VN nodes vary with the input signal VIN. Although many nonidealities can cause distortion, bias current modulation is one of the dominant distortion sources in this configuration.

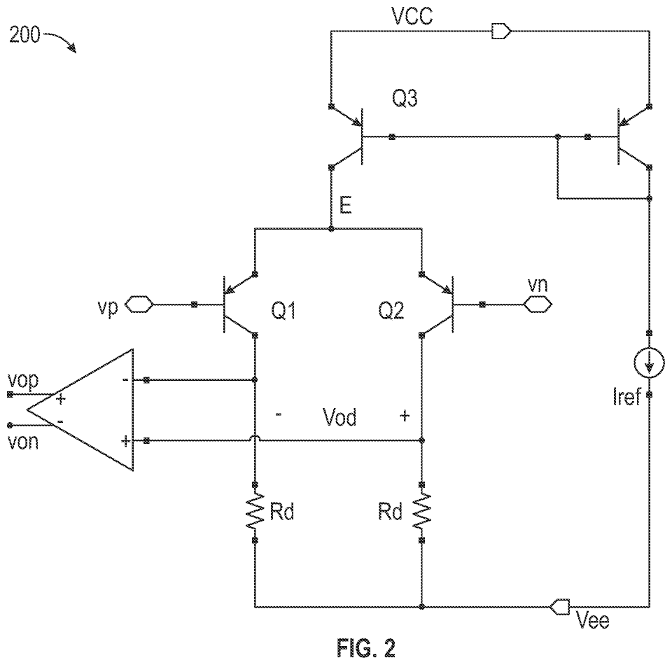

FIG. 2 is an example of an existing amplifier circuit. The origin of the tail current modulation and distortion is described as follows with respect to the amplifier circuit 200 of FIG. 2. For simplicity,

$$assume {V}_{in} ( t ) = {V}_{in} cos ( ω t ) \qquad [ 1 ]$$

where Vᵢₙ is the amplitude of the input signal, and ω is the signal frequency. The non-inverting node voltage of the operational amplifier is given by:

$${V}_{p} ( t ) = {V}_{p} cos ( ω t ) \qquad [ 2 ]$$

where Vₚ is the amplitude, which is a scaled version Vᵢₙ, depending on R_{G}, R_{F}, and V_{ocm}.

Furthermore, the differential voltage across non-inverting node and inverting node is approximately as

$${V}_{dm} ( t ) = {V}_{dm} cos ( ω t ) \qquad [ 3 ]$$

where V_{dm} is the amplitude of the differential signal, which is a function of output voltage V_{(vop, von)} and loop gain A_{L}(s) at the signal frequency.

$${V}_{dm} = \vert \frac{{V}_{( \text{?} )} ( t )}{{A}_{L} ( s )} \vert \qquad [ 4 ]$$

$$\text{?} \text{indicates text missing or illegible when filed}$$

For simplicity, assume Vᵢₙ(t), Vₚ(t), and V_{dm}(t) are in phase, i.e. phase shift is ignored. To maintain reasonable low distortion, V_{dm} is typically lower than ten millivolts. The voltage Vₚ is typically much greater than V_{dm}, thus, the operational amplifier common mode voltage may be approximated as the voltage at the non-inverting node, or:

$${V}_{cm} ( t ) = {V}_{p} cos ( ω t ) \qquad [ 5 ]$$

Collector currents of transistors Q1 and Q2 of the input stage of FIG. 2 are given by the following:

$${I}_{c 1} = \frac{β}{1 + β} \frac{{I}_{tail} ( t )}{1 + {e}^{- \text{?}}} \qquad [ 6 ]$$

$${I}_{c 2} = \frac{β}{1 + β} \frac{{I}_{tail} ( t )}{1 + {e}^{\text{?}}} \qquad [ 7 ]$$

$$\text{?} \text{indicates text missing or illegible when filed}$$

Therefore, the output voltage of the first stage is given by:

$${V}_{od} ( t ) = \frac{β}{1 + β} {I}_{tail} ( t ) {R}_{c} \frac{{e}^{\text{?}} - {e}^{- \text{?}}}{{e}^{\text{?}} + {e}^{- \text{?}}} \qquad [ 8 ]$$

$$\text{?} \text{indicates text missing or illegible when filed}$$

The exponential function expansion formula results in the following:

$${e}^{- \text{?}} = 1 - \frac{{V}_{dm} ( t )}{2 {V}_{T}} + \frac{1}{2} {( \frac{{V}_{dm} ( t )}{2 {V}_{T}} )}^{2} - \frac{1}{6} {( \frac{{V}_{dm} ( t )}{2 {V}_{T}} )}^{3} + \frac{1}{24} {( \frac{{V}_{dm} ( t )}{2 {V}_{T}} )}^{4} + … \qquad [ 9 ]$$

$${e}^{\text{?}} = 1 + \frac{{V}_{dm} ( t )}{2 {V}_{T}} + \frac{1}{2} {( \frac{{V}_{dm} ( t )}{2 {V}_{T}} )}^{2} + \frac{1}{6} {( \frac{{V}_{dm} ( t )}{2 {V}_{T}} )}^{3} + \frac{1}{24} {( \frac{{V}_{dm} ( t )}{2 {V}_{T}} )}^{4} + … \qquad [ 10 ]$$

$$\text{?} \text{indicates text missing or illegible when filed}$$

From equations [9] and [10], the following is found:

$${e}^{\text{?}} - {e}^{- \text{?}} = \frac{{V}_{dm} ( t )}{2 {V}_{T}} + \frac{1}{24} {( \frac{{V}_{dm} ( t )}{2 {V}_{T}} )}^{3} + … \qquad [ 11 ]$$

$${e}^{\text{?}} - {e}^{- \text{?}} = 2 + \frac{1}{4} {( \frac{{V}_{dm} ( t )}{2 {V}_{T}} )}^{2} + \frac{1}{192} {( \frac{{V}_{dm} ( t )}{2 {V}_{T}} )}^{4} + … \qquad [ 12 ]$$

$$\text{?} \text{indicates text missing or illegible when filed}$$

Assuming V_{dm}<<V_{T}, then,

$${e}^{\text{?}} - {e}^{- \text{?}} \approx \frac{{V}_{dm} ( t )}{{V}_{T}} \qquad [ 13 ]$$

$${e}^{\text{?}} + {e}^{- \text{?}} \approx 2 \qquad [ 14 ]$$

$$\text{?} \text{indicates text missing or illegible when filed}$$

From equation [8], [13], [14], and assuming β>>1, then we find that

$${V}_{od} ( t ) \approx {I}_{tail} ( t ) {R}_{c} \frac{{V}_{dm} ( t )}{2 {V}_{T}} \qquad [ 15 ]$$

The above approximation given by equations [13] and [14] lead to negligible error as long as V_{dm}(t) is sufficiently small compared to the threshold voltage V_{T}. In a non-limiting numerical example, assume V_{dm}(t)=10 mV, at room temperature, then

$${e}^{\text{?}} - {e}^{- \text{?}} = {e}^{\text{?}} - {e}^{- \text{?}} = 0.387 , and \frac{{V}_{dm} ( t )}{2 {V}_{T}} = 0.385 ,$$

$$\text{?} \text{indicates text missing or illegible when filed}$$

the error is only 0.5%. Meanwhile,

$${e}^{\text{?}} + {e}^{- \text{?}} = {e}^{\text{?}} + {e}^{- \text{?}} = 2.037 ,$$

$$\text{?} \text{indicates text missing or illegible when filed}$$

which only leads to error of 1.8%.

Because of the finite Early voltage of Q3 and parasitic capacitance at the node E, the bias current of the input differential pair is a nonlinear function of the common mode voltage V_{cm}(t) with coefficient of g₁, g₂, . . . , gₙ. The tail current is given by the following:

$${I}_{tail} ( t ) = {I}_{dc} + {g}_{1} {V}_{cm} ( t ) + {g}_{2} {V}_{cm}^{2} ( t ) + {g}_{3} {V}_{cm}^{3} ( t ) + … \qquad [ 16 ]$$

For simplicity, ignore higher order harmonic components for a moment, thus assume the following:

$${I}_{tail} ( t ) \approx {I}_{dc} + {g}_{1} {V}_{cm} ( t ) \qquad [ 17 ]$$

Combining equation [15] and [17] results in the following:

$${V}_{od} ( t ) = {[ {I}_{dc} + {g}_{1} {V}_{cm} ( t ) ]}_{c} \frac{{V}_{dm} ( t )}{2 {V}_{T}} \qquad [ 18 ]$$

From equation [3], [5], and [18],

$${V}_{od} ( t ) = \frac{{I}_{dc} {R}_{c} {V}_{dm}}{2 {V}_{T}} cos ( ω t ) + \frac{{g}_{1} {R}_{c} {V}_{dm} {V}_{p}}{4 {V}_{T}} {cos}^{2} ( ω t ) \qquad [ 19 ]$$

Therefore,

$${V}_{od} ( t ) = \frac{{I}_{dc} {R}_{c} {V}_{dm}}{2 {V}_{T}} cos ( ω t ) + \frac{{g}_{1} {R}_{c} {V}_{dm} {V}_{p}}{4 {V}_{T}} + \frac{{g}_{1} {R}_{c} {V}_{dm} {V}_{p}}{4 {V}_{T}} cos ( 2 ω t ) \qquad [ 20 ]$$

Thus, the intermodulation between bias current and the voltage across the input differential pair leads to the 2^{nd} order harmonics as well as DC offset. In the above derivation, only the DC and fundamental components of the bias current are considered. If its higher order harmonics are included in the analysis, the total harmonic distortion will be even worse. Therefore, to design low distortion amplifiers, it is essential to suppress bias current modulation.

In the above analysis, the base-collector capacitance C_{μ} of the input transistor was ignored. Besides being process dependent, the capacitance is linearly proportional to the device size, and non-linearly depends on the reverse bias voltage of base-collector junction.

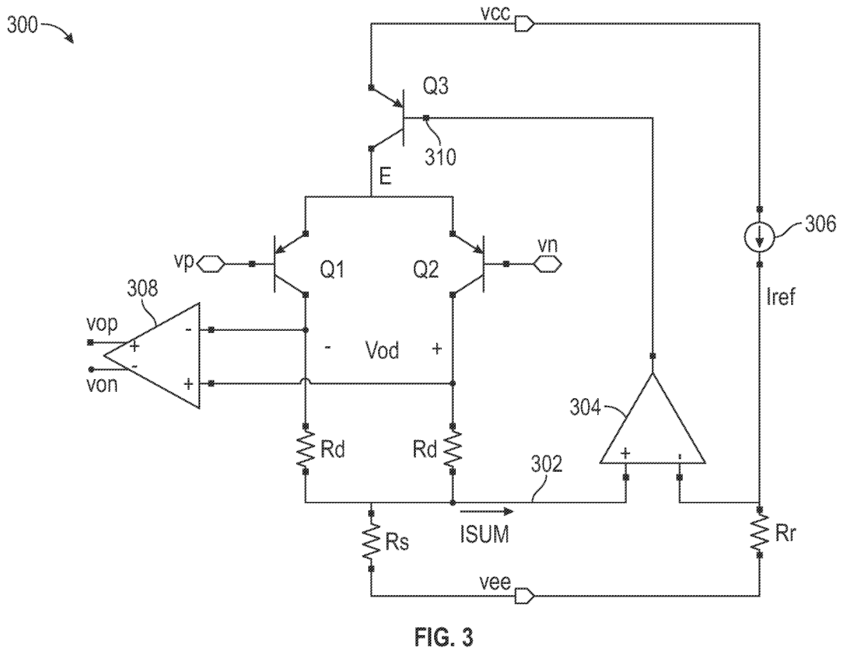

FIG. 3 is a schematic diagram of an example of an amplifier circuit that can implement various techniques of this disclosure. In the input stage, a regulation loop is utilized to maintain the sum of the collector current of the input differential pair constant. The regulation loop includes at least an input differential pair, a reference current, a sense resistor, an error correction amplifier, and a transistor, e.g., pass transistor. The amplifier circuit 300 shown in FIG. 3 includes bipolar junction transistors.

The amplifier circuit 300 includes a differential pair of transistors including transistor Q1 and transistor Q2. The transistor Q1 is configured to receive a positive input voltage Vp and the transistor Q2 is configured to receive a negative input voltage Vn. The differential pair of transistors Q1, Q2 is configured and arranged to generate a summed current from individual ones of the differential pair of transistors at node 302.

In some examples, the amplifier circuit 300 includes a first sense resistor Rs coupled with the differential pair of transistors, where the first sense resistor Rs is configured to generate the representation of the summed current at node 302 from the differential pair of transistors.

The amplifier circuit 300 further includes a transistor Q3, e.g., a pass transistor, coupled with the differential pair of transistors. For example, the emitter terminals of the differential pair of transistors are coupled together at node E, and node E is further coupled with the collector terminal of the transistor Q3.

An error correction amplifier 304 is coupled with a control terminal 310 of the transistor Q3, e.g., a base terminal. The summed current of the input differential pair of transistors is sensed, such as by the sense resistor Rs, and applied to the non-inverting input of the error correction amplifier 304. The error correction amplifier 304 compares a representation of the summed current to a representation of a reference current, such as generated by a reference current source 306, applied to an inverting input of the error correction amplifier 304. In some examples, the amplifier circuit 300 includes a second sense resistor Rr coupled with the reference current source 306, where the second sense resistor is configured to generate the representation of the reference current.

As seen in the example shown in FIG. 3, the reference current source 306 is coupled with control terminal 310 of the transistor Q3, e.g., the emitter of the transistor. The error correction amplifier 304 then adjusts, based on the comparison, the control voltage, e.g., base voltage, of the transistor Q3 to keep the current equal or proportional to the reference current.

In some examples, the collector of the transistor Q1 is coupled with a first resistor Rd and the collector of the transistor Q2 is coupled with a second resistor Rd.

The amplifier circuit 300 further includes gain stage 308 configured to receive a differential output voltage Vod, as generated between the collector of the transistor Q1 and the collector of the transistor Q2. The gain stage 308 generates differential output voltages Vop and Von.

In this manner, the amplifier circuit 300 of FIG. 3 provides a low distortion input stage with bias current regulation and includes at least three advantages over existing techniques: 1) higher output impedance; 2) wider input common mode range; 3) insensitive to the parasitic capacitances at Q1, Q2 emitters and Q3 collector.

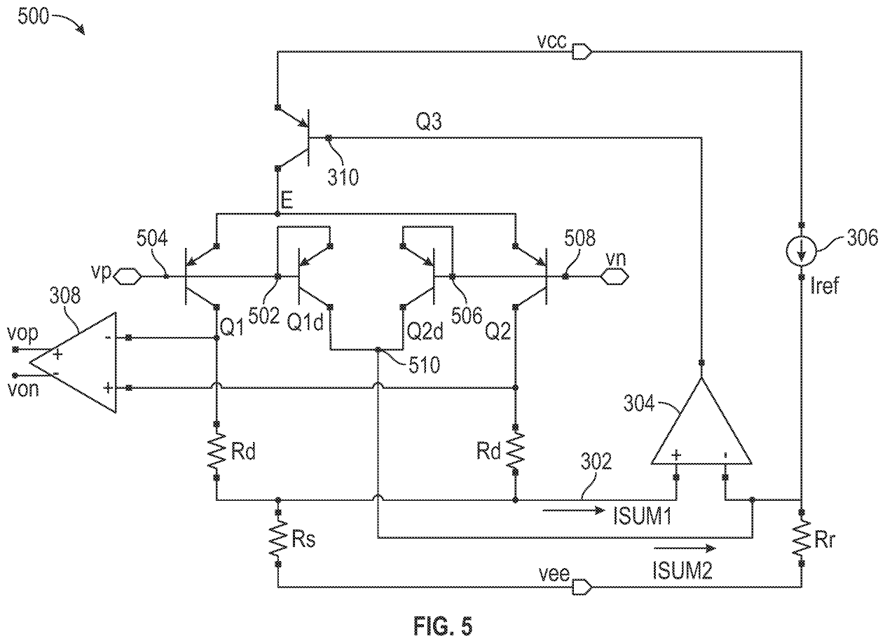

The displacement current through the capacitance is out of the regulation loop in FIG. 2, thus degrading the total harmonic distortion (THD). To further improve THD, as shown in FIG. 5, a second pair of transistors are included, e.g., replicas of the input transistors Q1 and Q2. The replicas remodulate the reference current of the regulation loop, thus cancelling the base-collector capacitive current of the input differential pair.

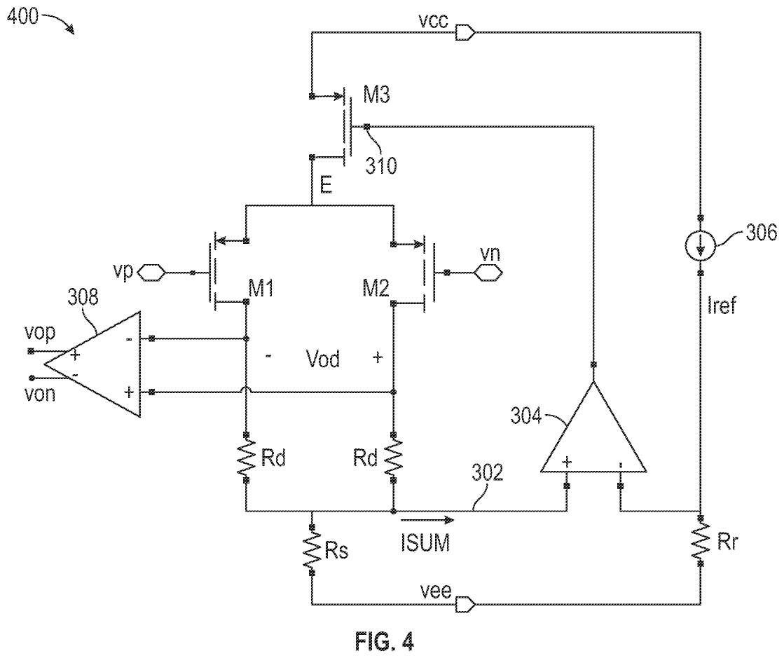

FIG. 4 is a schematic diagram of another example of an amplifier circuit that can implement various techniques of this disclosure. FIG. 4 includes features that are similar to those shown and described above with respect to FIG. 3 and similar reference numbers are used for such features. For brevity, those features will not be described again in detail.

In the example shown in FIG. 4, the amplifier circuit 400 includes field-effect transistors (FET) in contrast to the bipolar junction transistors (BJT) of the amplifier circuit 300 of FIG. 3. In particular, the differential pair of transistors in FIG. 4 includes FETs M1 and M2 and the BJT Q3 of FIG. 3 is replaced with the FET M3. The source terminals of the FETs M1 and M2 are connected at node E, and node E is coupled with the drain terminal of the FET M3.

The error correction amplifier 304 is coupled with the control terminal 310 of the FET M3, e.g., the gate terminal. The amplifier circuit 400 operates similarly to the amplifier circuit 300 of FIG. 3 and, for brevity, will not be described in detail again.

FIG. 5 is a schematic diagram of another example of an amplifier circuit that can implement various techniques of this disclosure. FIG. 5 includes features that are similar to those shown and described above with respect to FIG. 3 and similar reference numbers are used for such features. For brevity, those features will not be described again in detail.

The amplifier circuit 500 includes a second pair of transistors Q1d and Q2d. The transistor Q1d has a control terminal 502 coupled with a control terminal 504 of the transistor Q1 of the differential pair of transistors. The transistor Q2d has a control terminal 506 coupled with a control terminal 508 of the transistor Q2 of the differential pair of transistors. The control terminal 502 of the transistor Q1d is configured to receive the input signal Vp and the control terminal 506 of the transistor Q2d is configured to receive the input signal Vn.

A first summed current generated by the input differential pair of transistors is sensed, such as by the sense resistor Rs, and applied to the non-inverting input of the error correction amplifier 304. Similar to the differential pair of transistors Q1 and Q2, the pair of transistors Q1d and Q2d is configured and arranged to generate a second summed current at node 510 from individual ones of the transistors Q1d and Q2d. The summed current at node 510 is applied to the inverting input of the error correction amplifier 304 along with the reference current from the reference current source 306.

The error correction amplifier 304 compares a representation of the first summed current to a sum of a representation of the reference current and the second summed current. As seen in the example shown in FIG. 5, the reference current source 306 is coupled with the control terminal 310 of the transistor Q3, e.g., the emitter of the transistor. The error correction amplifier 304 then adjusts, based on the comparison, the control voltage, e.g., base voltage, of the transistor Q3 to keep the current equal or proportional to the reference current.

In some examples, the amplifier circuit 300 includes a second sense resistor Rr coupled with the reference current source 306, where the second sense resistor is configured to generate the representation of the reference current.

In some examples, individual ones of the second pair of transistors are replicas of the individual ones of the first differential pair of transistors. That is, the transistors Q1d and Q2d are replica transistors of the transistors Q1 and Q2. A “replica transistor” refers to a transistor that is designed and configured to mirror the electrical characteristics and behavior of another transistor within a circuit. This includes having substantially identical dimensions and layout to the target transistor, ensuring that the replica transistor's performance closely matches that of the target transistor under various operating conditions.

The pair of transistors Q1d and Q2d are included, e.g., replicas of the input transistors Q1 and Q2, to further improve THD. The replicas remodulate the reference current of the regulation loop, thus cancelling the base-collector capacitive current of the input differential pair Q1 and Q2.

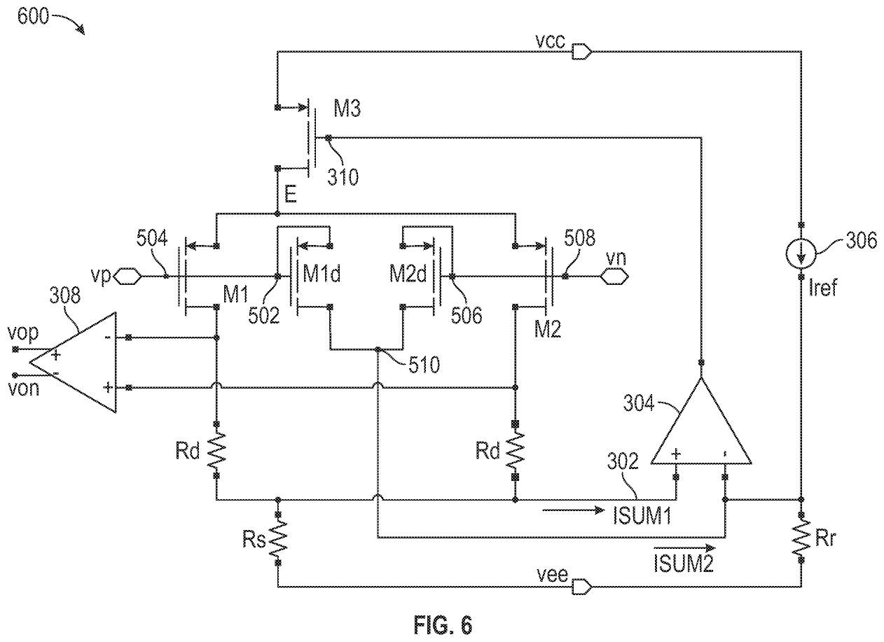

FIG. 6 is a schematic diagram of another example of an amplifier circuit that can implement various techniques of this disclosure. FIG. 6 includes features that are similar to those shown and described above with respect to FIG. 5 and similar reference numbers are used for such features. For brevity, those features will not be described again in detail.

In the example shown in FIG. 6, the amplifier circuit 600 includes field-effect transistors (FET) in contrast to the bipolar junction transistors (BJT) of the amplifier circuit 500 of FIG. 5. In particular, the differential pair of transistors in FIG. 6 includes FETs M1 and M2 coupled with FETs M1d and M2d, respectively, and the BJT Q3 of FIG. 5 is replaced with the FET M3. The source terminals of the FETs M1 and M2 are connected at node E, and node E is coupled with the drain terminal of the FET M3.

The error correction amplifier 304 is coupled with the control terminal 310 of the FET M3, e.g., the gate terminal. The amplifier circuit 600 operates similarly to the amplifier circuit 500 of FIG. 5 and, for brevity, will not be described in detail again.

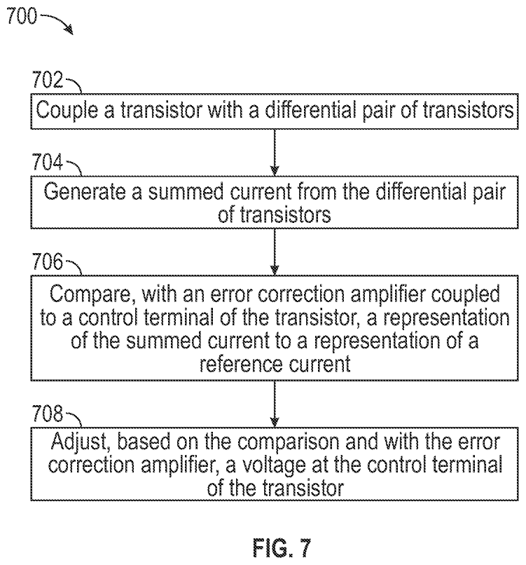

FIG. 7 is a flow diagram of an example of a method 700 for operating an amplifier circuit. At block 702, the method 700 includes coupling a transistor with a differential pair of transistors.

At block 704, the method 700 includes generating a summed current from the differential pair of transistors.

At block 706, the method 700 includes comparing, with an error correction amplifier coupled to a control terminal of the transistor, a representation of the summed current to a representation of a reference current.

At block 708, the method 700 includes adjusting, based on the comparison and with the error correction amplifier, a voltage at the control terminal of the transistor.

In some examples, the method 700 includes coupling a first sense resistor with the differential pair of transistors to generate the representation of the summed current from the differential pair of transistors.

In some examples, the method 700 includes coupling a reference current source with the transistor, and generating, via the reference current source, the reference current.

In some examples, the method 700 includes coupling a second sense resistor with the reference current source to generate the representation of the reference current.

In some examples, the differential pair of transistors is a first differential pair of transistors, wherein the first differential pair of transistors has a first control terminal to receive a first input signal and a second control terminal to receive a second input signal, and wherein the summed current is a first summed current, and the method 700 further includes coupling a second pair of transistors having a first control terminal with the first control terminal of the first differential pair of transistors; coupling a second control terminal with the second control terminal of the first differential pair of transistors; receiving, via the first control terminal of the second pair of transistors, the first input signal; receiving, via the second control terminal of the second pair of transistors, the second input signal; generating, via the second pair of transistors, a second summed current from individual ones of the second pair of transistors, wherein comparing, with the error correction amplifier, the representation of the summed current to the representation of the reference current, includes: comparing a representation of the first summed current to a sum of the representation of the reference current and the second summed current.

In some examples, coupling the transistor with the differential pair of transistors includes coupling a bipolar junction transistor with a differential pair of bipolar junction transistors.

In some examples, coupling the transistor with the differential pair of transistors includes coupling a field-effect transistor with a differential pair of field-effect transistors.

### VARIOUS NOTES

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. An amplifier circuit comprising:
a differential pair of transistors configured and arranged to generate a summed current from individual ones of the differential pair of transistors;
a transistor coupled with the differential pair of transistors; and
an error correction amplifier coupled with a control terminal of the transistor and configured for:
comparing a representation of the summed current to a representation of a reference current; and
adjusting, based on the comparison, a voltage at the control terminal of the transistor.

2. The amplifier circuit of claim 1, comprising:
a first sense resistor coupled with the differential pair of transistors, wherein the first sense resistor is configured to generate the representation of the summed current from the differential pair of transistors.

3. The amplifier circuit of claim 1, comprising:
a reference current source coupled with the transistor and configured to generate the reference current.

4. The amplifier circuit of claim 3, comprising:
a second sense resistor coupled with the reference current source, wherein the second sense resistor is configured to generate the representation of the reference current.

5. The amplifier circuit of claim 1, wherein the differential pair of transistors includes bipolar junction transistors.

6. The amplifier circuit of claim 1, wherein the differential pair of transistors includes field-effect transistors.

7. The amplifier circuit of claim 1, wherein the differential pair of transistors is a first differential pair of transistors, wherein the first differential pair of transistors has a first control terminal to receive a first input signal and a second control terminal to receive a second input signal, and wherein the summed current is a first summed current, the amplifier circuit further comprising:
a second pair of transistors having a first control terminal coupled with the first control terminal of the first differential pair of transistors and a second control terminal coupled with the second control terminal of the first differential pair of transistors, the first control terminal of the second pair of transistors to receive the first input signal and the second control terminal of the second pair of transistors to receive the second input signal,
wherein the second pair of transistors is configured and arranged to generate a second summed current from individual ones of the second pair of transistors, and
wherein the error correction amplifier configured to compare the representation of the summed current to the representation of the reference current is configured to:
compare a representation of the first summed current to a sum of the representation of the reference current and the second summed current.

8. The amplifier circuit of claim 7, wherein individual ones of the second pair of transistors are replicas of the individual ones of the first differential pair of transistors.

9. A method for biasing an amplifier circuit, the method comprising:
coupling a transistor with a differential pair of transistors;
generating a summed current from the differential pair of transistors;
comparing, with an error correction amplifier coupled to a control terminal of the transistor, a representation of the summed current to a representation of a reference current; and
adjusting, based on the comparison and with the error correction amplifier, a voltage at the control terminal of the transistor.

10. The method of claim 9, comprising:
coupling a first sense resistor with the differential pair of transistors to generate the representation of the summed current from the differential pair of transistors.

11. The method of claim 9, comprising:
coupling a reference current source with the transistor; and
generating, via the reference current source, the reference current.

12. The method of claim 9, comprising:
coupling a second sense resistor with a reference current source to generate the representation of the reference current.

13. The method of claim 9, wherein the differential pair of transistors is a first differential pair of transistors, wherein the first differential pair of transistors has a first control terminal to receive a first input signal and a second control terminal to receive a second input signal, and wherein the summed current is a first summed current, the method further comprising:
coupling a second pair of transistors having a first control terminal with the first control terminal of the first differential pair of transistors;
coupling a second control terminal with the second control terminal of the first differential pair of transistors;
receiving, via the first control terminal of the second pair of transistors, the first input signal;
receiving, via the second control terminal of the second pair of transistors, the second input signal;
generating, via the second pair of transistors, a second summed current from individual ones of the second pair of transistors;
wherein comparing, with the error correction amplifier, the representation of the summed current to the representation of the reference current, includes:
comparing a representation of the first summed current to a sum of the representation of the reference current and the second summed current.

14. The method of claim 13, wherein individual ones of the second pair of transistors are replicas of the individual ones of the first differential pair of transistors.

15. The method of claim 9, wherein coupling the transistor with the differential pair of transistors includes:
coupling a bipolar junction transistor with a differential pair of bipolar junction transistors.

16. The method of claim 9, wherein coupling the transistor with the differential pair of transistors includes:
coupling a field-effect transistor with a differential pair of field-effect transistors.

17. An amplifier circuit comprising:
a differential pair of transistors configured and arranged to generate a summed current from individual ones of the differential pair of transistors, the differential pair of transistors having a first control terminal to receive a first input signal and a second control terminal to receive a second input signal, wherein the differential pair of transistors is configured and arranged to generate a summed current;
a transistor coupled with the differential pair of transistors, the transistor having a third control terminal;
a first sense resistor coupled with the differential pair of transistors, wherein the first sense resistor is configured to generate a first voltage in response to the summed current from the differential pair of transistors;
a reference current source coupled with the transistor and configured to generate a reference current;
a second sense resistor coupled with the reference current source, wherein the second sense resistor is configured to generate a second voltage in response to the reference current; and
an error correction amplifier having:
a non-inverting input coupled with the first sense resistor and configured to receive the first voltage generated by the first sense resistor; and
an inverting input coupled with the second sense resistor and configured to receive the second voltage generated by the second sense resistor.

18. The amplifier circuit of claim 17, wherein the differential pair of transistors is a first differential pair of transistors, wherein the first differential pair of transistors has a first control terminal to receive a first input signal and a second control terminal to receive a second input signal, and wherein the summed current is a first summed current, the amplifier circuit further comprising:
a second pair of transistors having a first control terminal coupled with the first control terminal of the first differential pair of transistors and a second control terminal coupled with the second control terminal of the first differential pair of transistors, the first control terminal of the second pair of transistors to receive the first input signal and the second control terminal of the second pair of transistors to receive the second input signal,
wherein the second pair of transistors is configured and arranged to generate a second summed current from individual ones of the second pair of transistors, and
wherein the error correction amplifier configured to compare the representation of the summed current to the representation of the reference current is configured to:
compare a representation of the first summed current to a sum of the representation of the reference current and the second summed current.

19. The amplifier circuit of claim 18, wherein individual ones of the second pair of transistors are replicas of the individual ones of the first differential pair of transistors.

20. The amplifier circuit of claim 17, wherein the differential pair of transistors includes bipolar junction transistors.
